(19) United States
(12) Patent Application Publication
(10) Pub. No.: US 2016/0091547 A1
(43) Pub. Date: Mar. 31, 2016

(54) WEAR DETECTION SYSTEM AND A METHOD FOR DETECTING WEAR

(71) Applicant: SCHUNK BAHN-UND INDUSTRIETECHNIK GMBH, Wettenberg (DE)

(72) Inventors: Guntram Fleischhauer, Lohra/Kirchvers (DE); Daniel Pfeffer, Mücke (DE)

(21) Appl. No.: 14/785,648

(22) PCT Filed: Apr. 17, 2014
(86) PCT No.: PCT/EP2014/057870

§ 371 Date: Oct. 20, 2015

(30) Foreign Application Priority Data
Apr. 22, 2013 (DE) 10 2013 207 271.6

(51) Int. Cl. G01R 31/00; B60M 5/00

(52) U.S. Cl. CPC G01R 31/005; B60M 5/00

(57) ABSTRACT

The invention relates to a wear detection system, having an image processing device and a contact strip (10), as well as to a method for monitoring the wear of a contact strip for a current supply to vehicles based on contact wires, wherein said contact strip features at least one wear indicator marking (11), which is designed in such a manner that it can be captured by means of an image processing device, said image processing device being an infrared camera for the purpose of capturing said wear indicator marking.

The invention relates to a wear detection system, having an image processing device and a contact strip, as well as to a method for monitoring the wear of a contact strip for a current supply to vehicles based on contact wires.

Contact strips that are made of carbon are commonly employed for the purpose of a current supply to railway vehicles, but also to non-rail vehicles, via a contact wire. Due to their material properties, such contact strips are always subject to wear as a result of abrasion of the carbon material. When employing such contact strips, for instance on haulage engines of trains, said contact strips already need to be replaced before a final wear limit has been reached, in order to avoid dangerous operating statuses, defects or breakdowns. Although an emergency shutdown function is commonly integrated into contact strips, said function causing the contact strip to be lowered when a final degree of wear has been reached, or already prior to that, when the contact strip has suffered damage or has been broken, further current supply and thus further operation of the vehicle by means of said contact strip are no longer possible after such an emergency shutdown has been activated. In order to avoid such situations, the contact strips need to be inspected at regular intervals with regard to their degree of wear. Commonly, such inspections are effected by staff, wherein this is a complex task since the contact strips are attached on a roof of a vehicle, such as a haulage engine, and since special safety precautions have to be complied with owing to the high voltage that is applied to the contact wire, which is why such inspections can then only be carried out in railway maintenance depots. For avoiding these complex screening procedures, partially automated wear monitoring systems are known, said systems being able to send a signal that a wear limit has been reached.

Therefore, the present invention is based on the task of proposing a contact strip, a wear detection system and a method for detecting wear, which are able to send a signal concerning or capture a degree of wear in an automated and reliable fashion, at the same time being inexpensive to produce.

Said task is solved by a wear detection system having the features of claim 1 and by a method for monitoring wear having the features of claim 15.

The wear detection system in accordance with the invention comprises an image processing device and a contact strip for a current supply to vehicles based on contact wires, wherein said contact strip features at least one wear indicator marking, which is designed in such a manner that it can be captured by means of an image processing device, said image processing device being an infrared camera for the purpose of capturing said wear indicator marking.

The contact strip comprises a contact element which is usually made from carbon, and which can rest against a contact wire, thereby being able to produce an electrical connection thereto. Said contact element is held through a contact strip support, which is in turn attached on a so-called pantograph being attached on the roof of a vehicle for his part. Here, the contact element features at least one wear indicator marking, which is designed in such a manner that it can be captured by means of an image processing device. Since said marking is visually detected in an optical fashion, there is no risk of a transmission disruption of the type that can occur in radio-based wear detection systems. When the contact strip is produced, the wear indicator marking can directly be integrated into the same and does not make a complex separate production process necessary. Thus, a contact strip in accordance with the invention having a wear indicator marking can also be produced at considerably lowered costs than the known systems. In addition, such a contact strip does not require any maintenance and can be replaced after receiving an automatically generated message that a defined degree of wear has been reached.

In the wear detection system in accordance with the invention, the contact strip can be captured by means of an image processing device. Advantageously, the image processing device is a camera for capturing a wear indicator marking. It is possible to attach such a camera for capturing the wear indicator markings so as to be stationary along a path, which is passed by vehicles, on which a contact strip is attached. By way of such a wear detection system, a continuous monitoring of the degree of wear of the contact strips on passing vehicles can be ensured. It is, for instance, conceivable that, when a vehicle that has a contact strip having reached or exceeded a defined degree of wear passes along, an automatic message is generated by the wear detection system. Here, the camera of the wear detection system can particularly advantageously be attached to already existing infrastructure, e.g. bridges, masts or buildings. By way of such a wear detection system, a continuous and reliable monitoring of degrees of wear of contact strips on vehicles being bound to contact wires can be ensured. Complex screening procedures by operating staff can be omitted, whereby down times of the vehicles can be reduced and costs can be saved.

The camera of the wear detection system in accordance with the invention is designed as an infrared camera. If the wear indicator marking of the contact strip is designed in such a manner that there is a temperature difference between said marking and the rest of the material of the contact strip, said difference being detectable by the infrared camera, a susceptance to failure in the detection can be reduced by way of a wear detection system that is designed in such a manner. Such a system is especially resistant to bad lighting conditions, precipitation or fog. The camera can, for instance, also be attached within a tunnel, whereby effects of the weather can be avoided.

When the contact strip is used as intended, the same is worn down continuously since constant abrasion of the carbon arises at an upper side as a result of the contact to the contact wire. In order to be able to determine a degree of the wear or of the abrasion of the contact strip, one or more wear indicator markings can be integrated into the contact strip. If several wear indicator marking of the same kind are integrated into the contact strip, the detection reliability increases since the wear indicator markings can be designed so as to redundant with respect to each other. If, when the contact strip passes an image processing device, for instance, an optical obstacle is situated between the wear indicator marking and the image processing device in such a manner that the wear indicator marking cannot be captured by the image processing device, it can still be ensured that a degree of wear of the contact strip is detected due to the fact that, in the contact strip, there is another wear indicator marking that is redundant. In this way, it is conceivable that a plurality of wear indicator markings that are redundant with respect to one another is envisaged in the contact strip. On the basis of said wear indicator markings, a degree of wear of the contact strip can reliably be determined and thus complex screening procedures by the operating staff can be omitted.

Here, almost any geometrical shape of the wear indicator marking can be selected. It can be round, angular, edged or a combination thereof. For instance, the wear indicator marking can be designed in the shape of a cuboid, of a wedge, of a pyramid, of a cylinder, of a cone, of a polyhedron or of a combination of said shapes. If several wear indicator marking are envisaged in the contact strip, they can be designed differently. By designing a wear indicator marking in such a way, it can to be ensured that a degree of wear of the contact strip can be detected without failures and in a reliable fashion.

A degree of wear can be detected in that, as wear and tear of the contact strip increases and, finally, when a defined degree of wear is reached, an image of the contact strip that can be captured by the image processing device is different from an image of the contact strip before the defined degree of wear was exceeded. Thereby, it is particularly easy to be able to detect that a defined degree of wear has been reached.

In order to cause such an effect, the wear indicator marking can be embedded into a material of the contact strip, which allows for a simplified production and manipulation of the contact strip since no further components have to be attached or connected by wire to the contact strip.

Here, the image of the contact strip that can be captured by the image processing device can change in different manners. For instance, the contact strip can be designed in such a manner that, when a defined degree of wear of the contact strip is exceeded, the shape or an image of the contact strip experiences a change due to the fact that the wear indicator marking is revealed. Thereby, the image processing device can determine beyond doubt that a defined degree of wear has been reached.

In one embodiment, the wear indicator marking can be integrated into the contact strip in such a manner that it is initially covered by the material of the contact strip in such a manner that it cannot be captured by the image processing device.

In a further embodiment of the contact strip, the same can be designed in such a manner that the wear indicator marking is not covered up by the material of the contact strip and can therefore be captured by the image processing device from the beginning of the use of the contact strip until a defined degree of wear has been reached, towards the end of its lifetime.

Here, the wear indicator marking can preferably be embedded in a lateral plane of the contact strip facing the contact wire, such that the wear indicator marking is abraded by the contact wire to the same extent as the contact strip and that it has completely vanished after a defined degree of wear has been reached. This means that the change that can be captured by the image processing device in the shape or in the image of the contact strip is in this embodiment ensured by way of the consumption of the wear indicator marking.

In a particularly advantageous embodiment of the contact strip, the wear indicator marking is formed from a material that contrasts optically with the material of the contact strip, leading to capturing said wear indicator marking with the image processing device being particularly easy. The contrast that can optically be captured can be produced in that the wear indicator marking differs from the material of the contact strip in respect of its color, of its reflecting properties, of its surface roughness or of its thermodynamic properties, e.g. the heat capacity. It can, for instance, be formed from a carbon or graphite of a different color, which can reduce the configuration of the contact strip to one single material and ensure an entirely uniform abrasion of the contact strip and of the wear indicator marking. In order to reliably be able to withstand high temperatures, the wear indicator marking can in addition also be formed from a metal, e.g. aluminum, (stainless) steel, copper or any alloy that is adapted to the respective conditions. The wear indicator marking can, however, also be formed from any other suitable basic material.

In addition, the wear indicator marking can also be formed from a plastic material, such as polytetrafluoroethylene. This can considerably improve the possibility of coloring and thus the extent to which the wear indicator marking can be captured.

In a further embodiment, the wear indicator marking can be formed by a recess in the contact strip. Such a structural shape of the contact strip can be produced in a particularly simple and cost-effective fashion since no further material has to be introduced into the contact strip in order to do this. Here, the recess can either be open on the side of the contact strip facing the contact wire or it can feature an opening on the side facing away from the contact wire, or, in other words, form a hollow space in the contact strip. In addition, the recess can be arranged laterally, along a longitudinal edge of the contact strip on the level of a wear limit. This has an influence on the image of the contact strip that can be captured by the image processing device to the effect that the recess is either initially captured and vanishes as abrasion of the contact strip increases or that the recess can initially not be captured and can be captured when a defined degree of wear of the contact strip has been reached. Due to the wear indicator marking being configured as a recess, the same can be produced in a particulrly simple and cast-effective fashion since no further material is needed. In order to guarantee a sufficient temperature difference, which can be captured by an infrared camera, between the contact strip and the wear indicator marking, it is particularly advantageous for such a wear detection system to configure the wear indicator marking as a recess. The recess can also form a continuous channel through the contact strip between a side of the contact strip facing in a direction of travel and a side facing the contact wire, wherein the opening of the channel, on the side facing the contact wire, can initially be covered up by the material of the contact strip and can only be revealed as abrasion of the contact strip material increases. In the region of the recess, a lower temperature can prevail than in a surrounding region of the contact strip. Thereby, it is possible to employ an infrared camera as the image processing device, which camera is able to detect or capture this temperature difference and is able to determine a degree of wear of the contact strip because of that.

In a further particularly advantageous embodiment of the contact strip, the wear indicator marking can be designed in such a manner that an image of its longitudinal section along a vertical virtual axis, or, in other words, along a virtual axis that is orthogonal to the contact wire, changes. Thereby, it becomes possible that the image of the wear indicator marking that can be captured by the image processing device continuously changes as abrasion of the contact strip material increases. For instance, the wear indicator marking can be designed so as to be wedge-shaped in such a manner that the image of its cross-section continuously becomes larger or smaller as a result of increasing abrasion of the contact strip. On the basis of this continuously changing image of the wear indicator marking, not only two wear statuses, but a wear indication without any steps can be obtained.

A further possibility of designing the contact strip in such a manner that at least two degrees of wear can be captured may be envisaging at least two, or more, wear indicator markings in the contact strip. In this way, the image or the shape of the contact strip, which is captured by the image processing device, can experience a change by means of a first wear indicator marking when a first defined degree of wear has been reached and can experience a further change through a further wear indicator marking when a further defined degree of wear of the contact strip has been reached. In this way, it is possible, on the basis of wear indicator markings being arranged on different heights, to be able to capture a multiplicity of degrees of wear of the contact strip.

In addition, the contact strip can be designed in such a manner that the wear indicator marking is arranged in an edge region of the contact strip facing in a direction of travel or in an edge region of the contact strip facing away from the direction of travel, in such a manner that any damage or ruptures of a material of the contact strip can be captured in said edge region by means of the image processing device. In this manner, damaging of the contact strip, which has occurred during operation, can be detected and signaled, whereupon a more detailed examination of the status of the contact strip can be performed by operating staff. Here, the wear indicator marking can be arranged in an upper region within the contact strip in such a manner that the wear indicator marking is initially visible at the beginning of the lifetime of the contact strip and changes the image of the contact strip that can be captured by the image processing device when a wear limit of the contact strip is reached, to the effect that the wear indicator marking can no longer be detected. If damaging of the contact strip occurs in a region of the wear indicator marking before said degree of wear of the contact strip has been reached, wherein the wear indicator marking is equally damaged or completely ripped off, or taken off, this can equally be captured by the image processing device. The wear indicator marking can, however, also be arranged in a lower region within the contact strip in such a manner that it is only revealed when a defined degree of wear is reached, in such a manner that it can be detected by the image processing device. If damaging of the contact strip occurs in a region between the wear indicator marking and the contact wire before said degree of wear of the contact strip has been reached, the wear indicator marking can be uncovered, whereby damaging of the contact strip can be detected by the image processing device.

In the method in accordance with the invention for monitoring, with the help of a wear detection system, the wear of a contact strip for a current supply to vehicles based on contact wires, the wear detection system features an image processing device and a contact strip, wherein the contact strip features a wear indicator marking, wherein the wear indicator marking is captured by means of the image processing device, said image processing device being an infrared camera, by means of which the wear indicator marking is captured. Regarding the advantages of the method for monitoring wear, reference is made to the more detailed description of the contact strip in accordance with the invention and of the wear detection system in accordance with the invention.

The method can be configured particularly advantageously if, upon wear of the contact strip, at least one wear indicator marking that is integrated into the contact strip, and thus an image or a shape of the contact strip, experiences a change, and if an image processing device captures and evaluates said change, a degree of wear of the contact strip being determined thereby.

Further advantageous embodiments of the method result from the descriptions of the features contained in the dependent claims relating back to device claim 1.

In the following, the invention is explained in more detail with reference to the enclosed drawing.

In the figures:

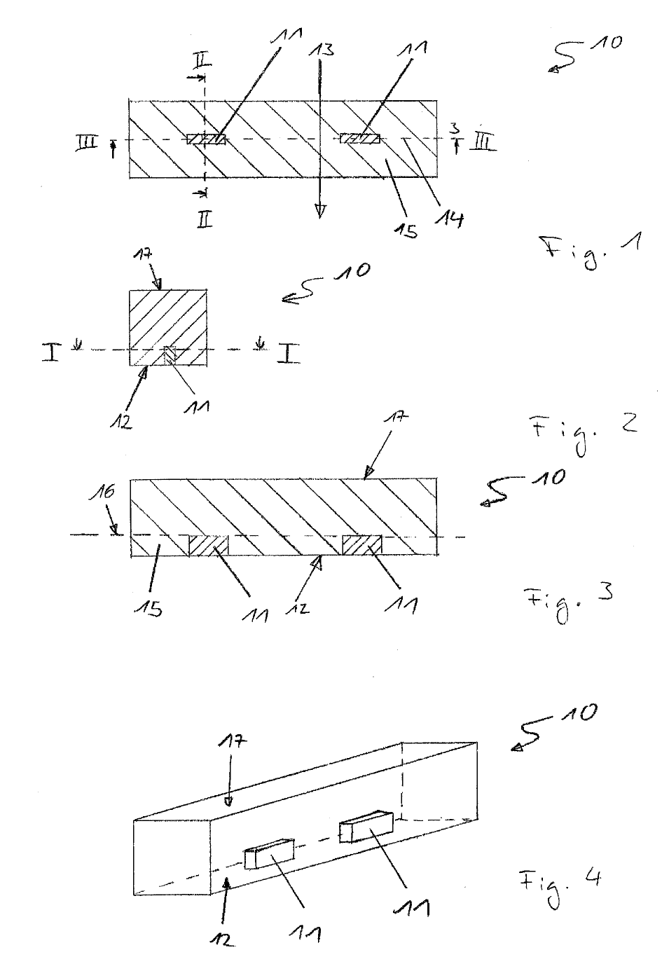

FIG. 1 shows a sectional view of a first embodiment of a contact strip along an axis I-I from FIG. 2;

FIG. 2 shows a sectional view of the contact strip along an axis II-II from FIG. 1;

FIG. 3 shows a sectional view of the contact strip along an axis III-III from FIG. 1;

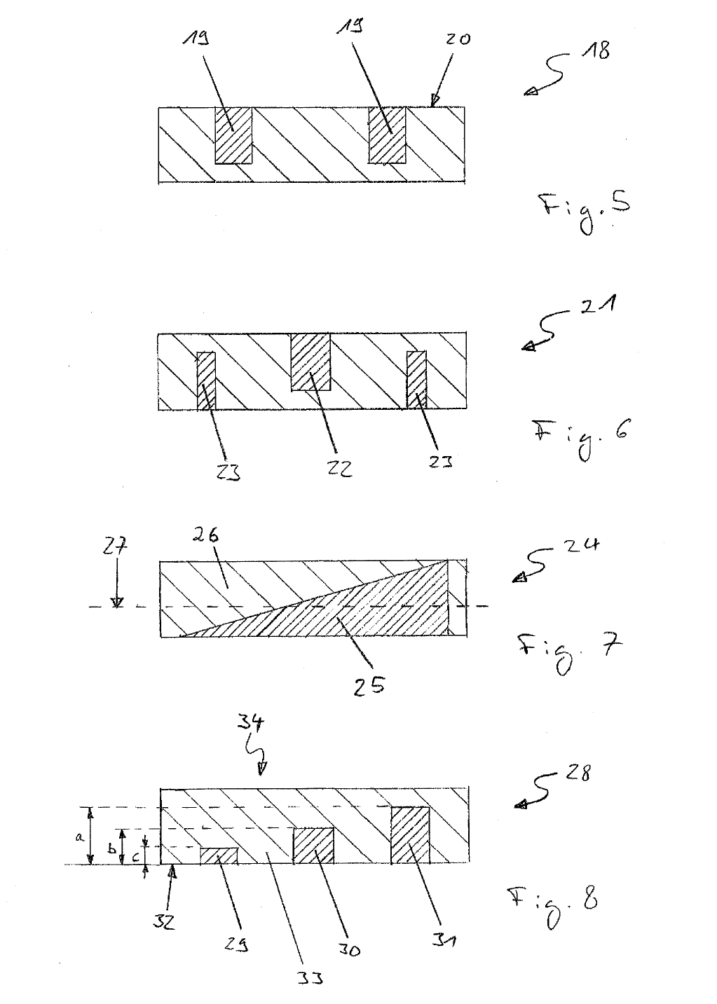

FIG. 4 shows a spatial representation of the contact strip;

FIG. 5 shows a longitudinal sectional view of a second embodiment of a contact strip;

FIG. 6 shows a longitudinal sectional view of a third embodiment of a contact strip;

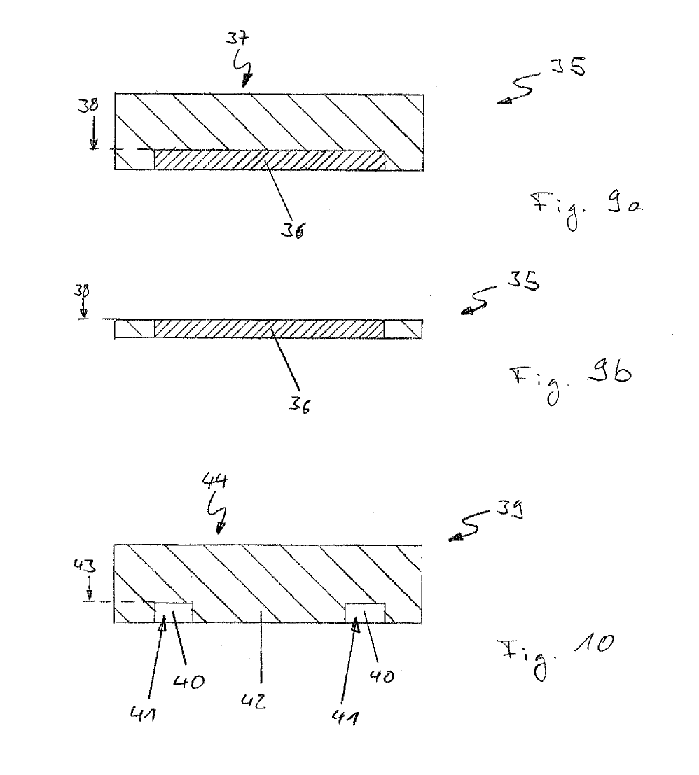

FIG. 7 shows a longitudinal sectional view of a fourth embodiment of a contact strip;

FIG. 8 shows a longitudinal sectional view of a fifth embodiment of a contact strip;

FIG. 9a shows a longitudinal sectional view of a sixth embodiment of a new, unused contact strip;

FIG. 9b shows a longitudinal sectional view of the used contact strip from FIG. 9a when a defined degree of wear has been reached;

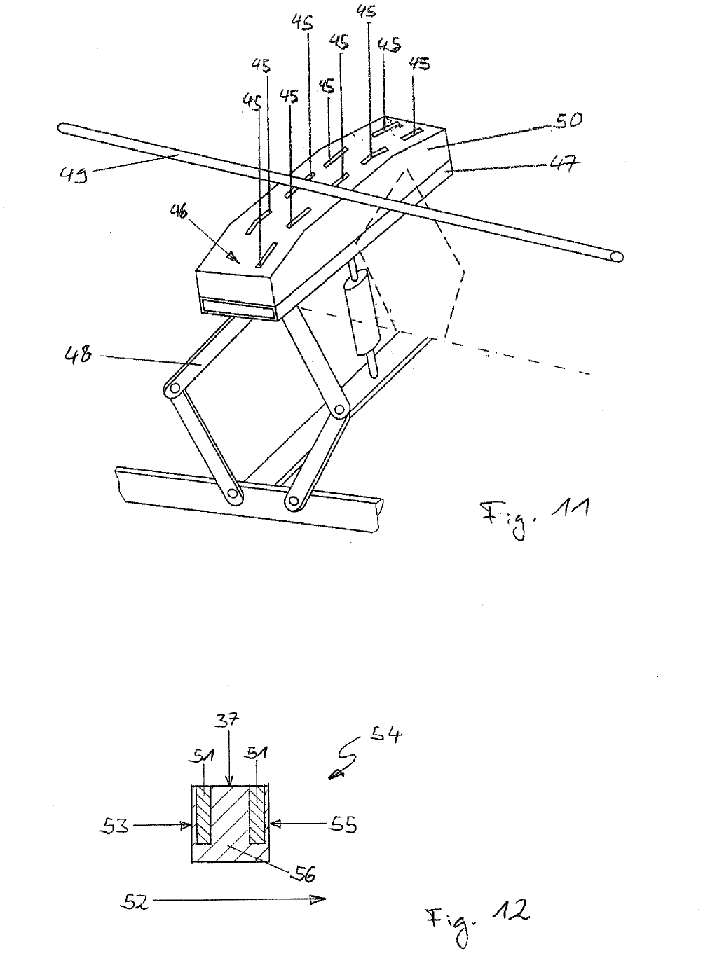

FIG. 10 shows a longitudinal sectional view of a seventh embodiment of a contact strip;

FIG. 11 shows a perspective view of a pantograph having an eighth embodiment of a contact strip;

FIG. 12 shows a cross-sectional view of a ninth embodiment of a contact strip.

A combined view of FIGS. 1 to 4 shows a first embodiment of a contact strip 10 having two wear indicator markings 11 in a schematic illustration, which markings are arranged within the contact strip 10, adjacent to a lower side 12 of the contact strip facing away from a contact wire that is not illustrated here, in a direction of travel 13 in the middle of the contact strip 10 so as to be uniform and symmetrical along a longitudinal axis 14.

FIG. 4 shows a spatial view of the contact strip 10. Here, the contact strip 10 is designed in such a manner that the wear indicator markings 11 are embedded into a contact strip material 15 of the contact strip 10 in such a manner that they can initially not be captured by an image processing device that is not illustrated here. When a degree of wear that is defined by way of a wear limit 16 is reached as a result of a use of the contact strip 10 as intended and of an abrasion of the contact strip material 15 accompanying the same, the wear indicator markings 11 are uncovered towards the end of a lifetime of the contact strip 10, which causes an image of an upper side 17 of the contact strip 10 that can be captured by the image processing device to be different from an image of the upper side 17 of the contact strip 10 before the defined degree of wear was exceeded. Since the wear indicator marking 11 forms an optical contrast to the rest of the material 15 of the contact strip 10 after the defined degree of wear of the contact strip 10 was exceeded, the degree of wear can be determined by the image processing device, leading to the image processing device, or, in other words, a computer that is connected to the image processing device and that is not illustrated here, either, being able to generate a message that the degree of wear of the contact strip 10 has been reached.

FIG. 5 shows a further embodiment of a contact strip 18 having wear indicator markings 19, which are arranged at an upper side 20 of the contact strip 18 within the same. The contact strip 18 is designed in such a manner that the wear indicator markings 19, at the beginning of their service life, can already be captured by an image processing device that is not illustrated here, wherein, upon reaching a defined degree of wear, the wear indicator marking 19 has completely been consumed, leading to an image of the contact strip 18 that can be captured by the image processing device changing, which equally indicates that a defined degree of wear has been exceeded.

FIG. 6 shows a third embodiment of a contact strip 21, wherein wear indicator markings 22 and 23 are designed in such a manner that, at the beginning of a service life of the contact strip 21, a part of wear indicator marking 22 or, in other words, an image of the wear indicator marking can be captured by an image processing device that is not shown, and that, as a result of increasing abrasion of the contact strip 21, wear indicator marking 23 is exposed when a first defined degree of wear is reached and can in this way be captured by the image processing device. When a further defined degree of wear of the contact strip 21 is reached, wear indicator marking 22, which can already be captured at the beginning of the service life of the contact strip 14, has been consumed completely, leading to capturing said wear indicator marking with the image processing device no longer being possible, whereby a further defined degree of wear of the contact strip 21 is indicated.

FIG. 7 shows a fourth embodiment of a contact strip 24 having a wedge-shaped wear indicator marking 25, wherein the wear indicator marking 25 is designed in such a manner that, at the beginning of a service life of the contact strip, only a very small portion or no portion of the wear indicator marking 25 can be captured by an image processing device that is not illustrated here, wherein, as wear of the contact strip 24 increases as a result of abrasion of a contact strip material 26 owing to a wedge shape of the wear indicator marking 25, an image of the contact strip 24 that can be captured by the image processing device changes continuously to the effect that a longitudinal sectional surface 27 of the wear indicator marking 25 that can be captured by the image processing device increases steadily. Thus, on the basis of a surface area that is captured by the image processing device or of a visible length of the wear indicator marking 25, a degree of wear of the contact strip 24 can be determined without any steps.

FIG. 8 shows a fifth embodiment of a contact strip 28 having wear indicator markings 29, 30, 31, which are arranged within the contact strip 28 starting from a lower side 32 and feature different heights a, b, c, wherein, as a result of increasing abrasion of a contact strip material 33, wear indicator marking 31 initially becomes evident at an upper side 34 of the contact strip 28 when a first defined degree of wear of the contact strip 28 is reached and can be captured by an image processing device, wherein wear indicator marking 30 becomes evident when a second defined degree of wear is reached and can be captured by the image processing device, and wherein wear indicator marking 29, when a third degree of wear of the contact strip 28 is reached, changes an image of the upper side 34 of the contact strip 28 to the effect that it is indicated that a further defined degree of wear of the contact strip 28 has been reached.

FIG. 9a shows a sixth embodiment of a contact strip 35 having a wear indicator marking 36, wherein the wear indicator marking 36 is arranged in such a manner that the image of an upper side 37 of the contact strip 35, when a defined degree of wear of the contact strip 35 is reached, has experienced a change to the effect that a defined degree of wear is indicated when a wear limit 38 is reached.

FIG. 9b shows the contact strip 35 after the defined degree of wear of the contact strip 35 has been reached. The wear indicator marking 36 can now be captured by an image processing device that is not shown here, whereby it is indicated that the defined degree of wear has been reached.

FIG. 10 shows a seventh embodiment of a contact strip 39 having a wear indicator marking 40, wherein the wear indicator marking 40 of said embodiment is formed by recesses 41 in a material 42 of the contact strip 39. Here, the recesses 41 are designed in such a manner that they are revealed when a defined degree of wear 43 of the contact strip 39 is reached, wherein this changes an image of an upper side 44 of the contact strip 39 that can be captured by an image processing device to the effect that wear of the contact strip 39 is indicated.

FIG. 11 shows an eight embodiment of a contact strip 50 having wear indicator markings 45, which are uniformly distributed over a surface 46 of the contact strip 50. In FIG. 11, the contact strip 50 is illustrated on a contact strip support 47, which is for his part attached on a pantograph 48, which is capable of lifting and lowering the contact strip 50. The contact strip 50 rests against a contact wire 49, leading to an electrically conductive connection between the contact strip 50 and the pantograph 48 having been produced.

FIG. 12 shows a ninth embodiment of a contact strip 54 having wear indicator markings 51, which are arranged in an edge region 53 of the contact strip 54 facing in a direction of travel 52 as well as in an edge region 55 of the contact strip 54 facing away from the direction of travel. Moreover, the wear indicator markings 51 are arranged at an upper side 57 of the contact strip 54 within the same in such a manner that the wear indicator markings 51 can already be captured by an image processing device that is not illustrated here at the beginning of the service life of the contact strip 54, wherein, when a defined degree of wear is reached, the wear indicator markings 51 have been consumed completely, leading to an image of the contact strip 54 that can be captured by the image processing device changing, which indicates that a defined degree of wear was exceeded. If the contact strip 54 is damaged during its service life in such a manner that pieces of the contact strip material 56 are broken out in one of the edge regions 53, 55 of the contact strip 54, an image of the contact strip 54 that can be captured by the image processing device and of the wear indicator markings 51 has experienced a change in such a manner that a damaging of the contact strip 54 is indicated.

1. A wear detection system, said system comprising:
an image processing device in the form of an infrared camera;
a contact strip for a current supply to vehicles based on contact wires; and
at least one wear indicator marking, indicating wear on said contact strip from the contact wires, said image processing device capturing at least one image of said at least one indicator marking indicating said wear.

2. The wear detection system according to claim 1, in which a degree of wear can be determined by one or more of said at least one wear indicator markings.

3. The wear detection system according to claim 1, in which the contact strip is designed in such a manner that, when a defined degree of wear of the contact strip is exceeded, an image of the contact strip captured by the image processing device is different from an image of the contact strip before the defined degree of wear was exceeded.

4. The wear detection system according to claim 1, in which the at least one wear indicator marking 2, 23, 25, 29, 30, 31, 36, 45, 51) is embedded into a material (33) of the contact strip (10, 18, 21, 24, 28, 35, 39, 50, 54).

5. The wear detection system is designed in such a manner that, when a defined degree of wear of the contact strip is exceeded, a shape or an image of the contact strip is different due to the fact that the at least one wear indicator marking is revealed.

6. The wear detection system according to claim 1, in which the contact strip is designed in such a manner that, until a defined degree of wear of the contact strip is exceeded, the at least one wear indicator marking is covered by the material of the contact strip in such a manner that it said at least one wear marking cannot be captured by the image processing device.

7. The wear detection system according to claim 1, in which the contact strip is designed in such a manner that, until a defined degree of wear of the contact strip is exceeded, the at least one wear indicator marking can be captured by the image processing device.

8. The wear detection system according to claim 7, in which when a defined degree of wear of the contact strip is exceeded, a shape of the contact strip is different due to the fact that the wear indicator marking has been worn down completely.

9. The wear detection system according to claim 1, in which the at least one wear indicator marking forms an optical contrast to a material of the contact strip.

10. The wear detection system according to claim 1, in which the at least one wear indicator marking is formed from plastic.

11. The wear detection system according to claim 1, in which the at least one wear indicator marking is a recess in the contact strip.

12. The wear detection system according to claim 1, in which the at least one wear indicator marking is designed in such a manner that the image of the wear indicator marking captured by the image processing device continuously changes as wear increases.

13. The wear detection system according to claim 1, in that in which the contact strip (21, 28) comprises includes at least two wear indicator markings arranged in the contact strip in such a manner that a first wear indicator marking of said at least two wear indicator markings indicates that a first defined degree of wear has been reached and that a second wear indicator marking of said at least two wear indicator markings indicates that second defined degree of wear has been reached.

14. The wear detection system according to claim 1, in which the at least one wear indicator marking is arranged in an edge of the contact strip facing away from the direction of travel, in such a manner that any damage or ruptures of a material of the contact strip can be captured in said edge region by the image processing device.

15. A method for monitoring, wear of a contact strip for a current supply to vehicles based on contact wires, said method comprising:
capturing images of a wear indicator marking on a contact strip using an infrared camera.

16. The method according to claim 15 in which upon wear of the contact strip us an image or a shape of the contact strip, experiences a change, said method including es
capturing said images of said wear indicator marking change with said infrared camera, and
determining a degree of wear of the contact strip based on said images of said wear indicator marking change.
